(19) United States
(12) Patent Application Publication
(10) Pub. No.: US 2025/0081582 A1
(43) Pub. Date: Mar. 6, 2025

(54) SEMICONDUCTOR DEVICE

(71) Applicant: SUMITOMO ELECTRIC DEVICE INNOVATIONS, INC., Yokohama-shi (JP)

(72) Inventors: James WONG, Yokohama-shi (JP); Kento KAWASAKI, Yokohama-shi (JP)

(73) Assignee: SUMITOMO ELECTRIC DEVICE INNOVATIONS, INC., Yokohama-shi (JP)

(21) Appl. No.: 18/812,031

(22) Filed: Aug. 22, 2024

(30) Foreign Application Priority Data
Aug. 28, 2023 (JP) 2023-138187

(51) Int. Cl. H01L 29/423; H01L 23/522; H01L 23/528; H01L 29/417

(52) U.S. Cl. CPC H10D 64/512; H01L 23/5226; H01L 23/5286; H10D 64/254; H10D 64/258

(57) ABSTRACT

A semiconductor device according to the present disclosure includes a source electrode provided on a substrate, a gate electrode provided-on the substrate and surrounding a part of the source electrode, a drain electrode provided on the substrate and surrounding the gate electrode, and a gate wiring provided on the substrate, wherein a first end of the gate wiring is connected to only one portion of the gate electrode and a second end of the gate wiring is connected to a first gate bus bar.

### CROSS REFERENCE TO RELATED APPLICATIONS

The application claims priority based on Japanese Patent Application No. 2023-138187 filed on Aug. 28, 2023, and the entire contents of the Japanese patent application are incorporated herein by reference.

### FIELD OF THE INVENTION

A certain aspect of the embodiments is related to a semiconductor device.

### BACKGROUND OF THE INVENTION

In a field effect transistor (FET) having a finger-shaped source electrode, a finger-shaped gate electrode, and a finger-shaped drain electrode, it is known that a plurality of unit FETs having a source electrode, a gate electrode, and a drain electrode are arranged in the extending direction of the electrodes (for example, Patent Document 1: Japanese Laid-Open Patent Publication No. 2002-299351).

### SUMMARY OF THE INVENTION

A semiconductor device according to an embodiment of the present disclosure includes a source electrode provided on a substrate; a gate electrode provided-on the substrate and surrounding a part of the source electrode; a drain electrode provided on the substrate and surrounding the gate electrode; and a gate wiring provided on the substrate, wherein a first end of the gate wiring is connected to only one portion of the gate electrode and a second end of the gate wiring is connected to a first gate bus bar.

### BRIEF DESCRIPTION OF THE DRAWINGS

FIG. 1 is a plan view of a semiconductor device according to a first embodiment.

FIG. 2 is a cross-sectional view taken along line A-A in FIG. 1.

FIG. 3 is a plan view of a semiconductor device according to a first comparative example.

FIG. 4 is a plan view of a semiconductor device according to a second comparative example.

FIG. 5 is a plan view of a semiconductor device according to a first modification of the first embodiment.

FIG. 6 is a plan view of a semiconductor device according to a second modification of the first embodiment.

FIG. 7 is a plan view of a semiconductor device according to a second embodiment.

FIG. 8 is a plan view of a semiconductor device according to a first modification of the second embodiment.

FIG. 9 is a plan view of a semiconductor device according to a second modification of the second embodiment.

FIG. 10 is a plan view of a semiconductor device according to a third modification of the second embodiment.

FIG. 11 is a plan view of a semiconductor device according to a third embodiment.

### DETAILED DESCRIPTION

When a plurality of unit FETs are arranged, it is difficult to miniaturize the semiconductor device. When the semiconductor device is to be miniaturized, the design may become difficult.

The present disclosure has been made in view of the above problems, and an object thereof is to reduce the size of the apparatus.

### Description of Embodiments of the Present Disclosure

First, the contents of the embodiments of the present disclosure will be enumerated and described.

(1) A semiconductor device according to an embodiment of the present disclosure includes a source electrode provided on a substrate; a gate electrode provided on the substrate and surrounding a part of the source electrode; a drain electrode provided on the substrate and surrounding the gate electrode; and a gate wiring provided on the substrate, wherein a first end of the gate wiring is connected to only one portion of the gate electrode and a second end of the gate wiring is connected to a first gate bus bar. This allows the semiconductor device to be easily designed and reduced in size.

(2) In the above (1), the gate electrode may be provided in a loop shape on the substrate.

This allows miniaturization.

(3) In the above (1), the drain electrode may be provided on the substrate and may surround the gate electrode in a first direction, a direction opposite to the first direction, and a second direction intersecting the first direction. This allows miniaturization.

(4) In the above (3), the drain electrode may surround the gate electrode only from the first direction, the direction opposite to the first direction, and the second direction. This allows miniaturization.

(5) In the above (3), the first end of the gate wiring may be connected to a portion of the gate electrode not surrounded by the drain electrode in a direction opposite to the second direction, within a range having a width of ½ of a width of the portion in the first direction with a center point in the first direction. This makes it possible to make the gate widths of the two FETs effectively connected in parallel close to each other, and thus the design becomes easier.

(6) In the above (3), the drain electrode may surround the gate electrode from a direction opposite to the second direction. This makes it possible to increase the effective gate width, thereby making it possible to reduce the size of the device.

(7) In the above (3), a width of the source electrode in the second direction may be not more than three times and not less than one third times the width of the source electrode in the first direction. This improves the heat dissipation.

(8) In any one of the above (1) to (7), the semiconductor device may further include a metal layer provided under the substrate and electrically connected to the source electrode via a via hole penetrating the substrate. This allows miniaturization.

(9) In the above (3), the substrate may have an active region in which a semiconductor layer in the substrate is activated, and a region of the drain electrode surrounding the gate electrode in the first direction, the direction opposite to the first direction, and the second direction is provided on the active region. This allows miniaturization.

(10) In the above (3), the semiconductor device may further include FET groups each including a plurality of unit FETs arranged in the first direction, each of the unit FETs including the source electrode, the gate electrode, and the drain electrode, and adjacent ones of the unit FETs sharing the drain electrode, and a drain bus bar to which drain electrodes of a plurality of unit FETs in a first FET group among the FET groups are connected, the first FET group being interposed between the first gate bus bar and the drain bus bar, the first gate bus bar being connected to gate wirings of the plurality of unit FETs in the first FET group. This facilitates the design of the semiconductor device having a large gate width.

(11) In the above (10), the semiconductor device may further include a second FET group included in the FET groups, the drain bus bar being interposed between the first FET group and the second FET group, and a second gate bus bar connected to a plurality of unit FETs included in the second FET group interposed between the drain bus bar and the second gate bus bar. This facilitates the design of the semiconductor device having a large gate width.

(12) In the above (11), a width of the drain bus bar in the second direction may be larger than a width of the drain electrode shared by the unit FETs adjacent to each other in the first direction. This makes it possible to make the current density of the drain bus bar close to the current density of the drain electrode, thereby making it possible to reduce the size of the device.

(13) In the above (11) or (12), the semiconductor device may further include a gate pad electrically connecting the first gate bus bar and the second gate bus bar, and a drain pad electrically connected to the drain bus bar, the first FET group and the second FET group being interposed between the drain pad and the gate pad. This allows the gate pad and the drain pad to be efficiently arranged, thereby enabling miniaturization.

(14) In any one of the above (11) to (13), the semiconductor device may further include a plurality of unit arranged in the second direction, each of the plurality of units including the first FET group, the second FET group, the drain bus bar, the first gate bus bar, and the second gate bus bar. This allows the unit FETs to be efficiently arranged, thereby enabling miniaturization.

A description will be given, with reference to the accompanying drawings, of embodiments of semiconductor devices according to the present disclosure. It is to be understood that the present disclosure is not limited to these embodiments, but is intended to be set forth by the appended claims and to include all modifications within the meaning and scope of the equivalents of the appended claims.

### FIRST EMBODIMENT

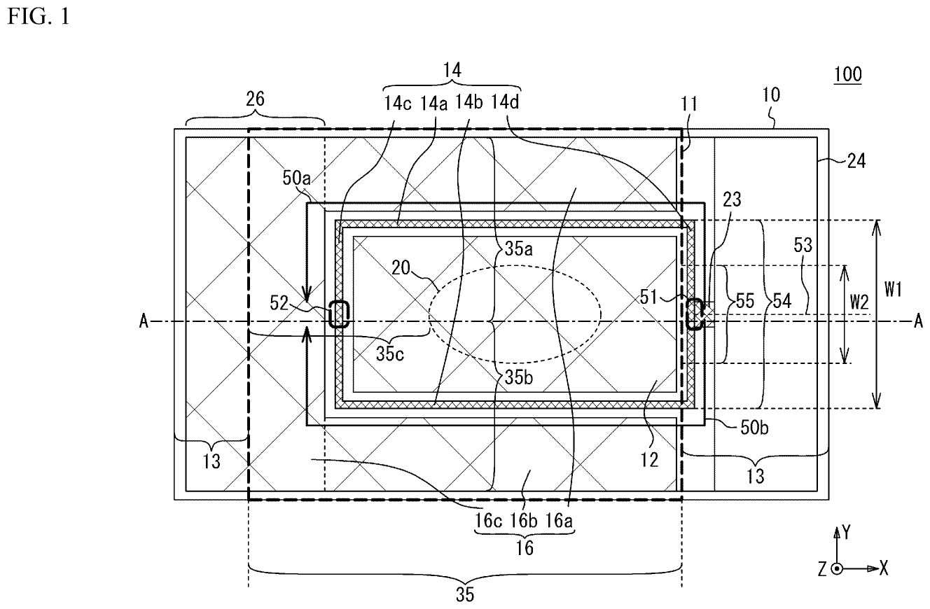

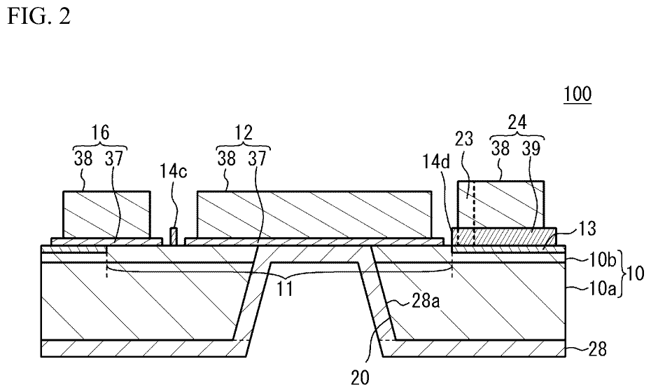

FIG. 1 is a plan view of a semiconductor device according to a first embodiment. FIG. 2 is a cross-sectional view taken along the line A-A in FIG. 1. The thickness direction of a substrate 10 is defined as a Z direction, the direction in which a source electrode 12 is interposed between a drain electrode 16c and a gate bus bar 24 is defined as an X direction, and the direction in which the source electrode 12 is interposed between the drain electrodes 16a and 16b is defined as a Y direction.

As illustrated in FIGS. 1 and 2, in a semiconductor device 100 of the first embodiment, the substrate 10 includes a substrate 10a and a semiconductor layer 10b provided on the substrate 10a. In the XY plane parallel to the X direction and the Y direction, a region where the semiconductor layer 10b is inactivated by ion implantation or the like is an inactive region 13. An active region 11 is a region where the semiconductor layer 10b is not inactivated but activated.

The source electrode 12, a gate electrode 14, a drain electrode 16, a gate wiring 23, the gate bus bar 24, and a drain bus bar 26 are provided on the substrate 10. A unit FET 35 includes the source electrode 12, the gate electrode 14, and the drain electrode 16.

The source electrode 12 has a substantially rectangular shape in plan view, with sides extending in the X and Y directions. The gate electrode 14 is provided in a loop shape so as to surround the source electrode 12. The gate electrode 14 includes gate electrodes 14a to 14d. The gate electrodes 14a and 14b extend in the X direction, and the source electrode 12 is interposed therebetween in the Y direction. The gate electrodes 14c and 14d extend in the Y direction, and the source electrode 12 is interposed therebetween in the X direction.

The drain electrode 16 surrounds the gate electrode 14 in the +direction (first direction) in the Y direction, the-direction (direction opposite to the first direction) in the Y direction, and the-direction (second direction perpendicular to the first direction) in the X direction. The drain electrode 16 includes drain electrodes 16a to 16c. The gate electrodes 14a to 14c are interposed between the drain electrodes 16a to 16c and the source electrode 12, respectively. The source electrode 12, the gate electrodes 14a to 14c, and the drain electrodes 16a to 16c are provided on the active region 11 of the substrate 10.

The unit FET 35 has unit FETs 35a to 35c. The unit FET 35a includes the source electrode 12, the gate electrode 14a, and the drain electrode 16a. The unit FET 35b includes the source electrode 12, the gate electrode 14b, and the drain electrode 16b. The unit FET 35c includes the source electrode 12, the gate electrode 14c, and the drain electrode 16c.

The gate electrode 14d is provided on the inactive region 13 of the substrate 10. The gate bus bar 24 is provided in a region on the inactive region 13 of the substrate 10 provided in the +direction in the X direction of the gate electrode 14d, and extends in the Y direction. The gate wiring 23 is provided on the inactive region 13, and electrically connects and short-circuits the gate electrode 14d and the gate bus bar 24.

The drain bus bar 26 includes the drain electrode 16c and the drain electrode 16 provided on the inactive region 13, and extends in the Y direction. The unit FET 35 is interposed between the gate bus bar 24 and the drain bus bar 26 in the X direction.

The via hole 20 penetrates the substrate 10 and connects to the source electrode 12. A metal layer 28 is provided on the lower surface of the substrate 10. A metal layer 28a is provided on the inner surface of the via hole 20. As a result, the metal layer 28 is electrically connected to the source electrode 12 through the via hole 20, and is short-circuited. A reference potential such as a ground potential is supplied to the metal layer 28.

When the semiconductor device 100 is, for example, a nitride semiconductor device, the substrate 10a is, for example, a silicon carbide (SiC) substrate, a silicon substrate, a gallium nitride (GaN) substrate, or a sapphire substrate. The semiconductor layer 10b includes a nitride semiconductor layer such as a gallium nitride layer, an aluminum gallium nitride (AlGaN) layer, and/or an indium gallium nitride (InGaN) layer. When the unit FET 35 is a GaN HEMT (Gallium Nitride High Electron Mobility Transistor), the semiconductor layer 10b includes a gallium nitride channel layer provided on the substrate 10a and an aluminum gallium nitride barrier layer provided on the gallium nitride channel layer. When the semiconductor device 100 is, for example, a gallium arsenide (GaAs)—based semiconductor device, the substrate 10a is, for example, a gallium arsenide substrate. The semiconductor layer 10b includes an arsenide semiconductor layer, such as, for example, a gallium arsenide layer, an aluminum gallium arsenide (AlGaAs) layer and/or an indium gallium arsenide (InGaAs) layer. The semiconductor device 100 may be a silicon semiconductor device such as LDMOS (Laterally Diffused Metal Oxide Semiconductor).

The source electrode 12 and the drain electrode 16 include an ohmic contact layer 37 and a low resistance layer 38. The gate wiring 23 and the gate bus bar 24 include a gate metal layer 39 and the low resistance layer 38. The ohmic contact layer 37 is a metal layer in ohmic contact with the semiconductor layer 10b, and is formed of, for example, a titanium film and an aluminum film, which are arranged in the order of the substrate 10. The low resistance layer 38 is a metal layer having a lower resistivity than that of an ohmic contact layer such as a gold layer. The gate electrode 14 and the gate metal layer 39 are metal films, and for example, are a nickel film and a gold film from the substrate 10 side. An insulating layer may be provided so as to cover the source electrode 12, the gate electrode 14, the drain electrode 16, the gate wiring 23, and the gate bus bar 24. The insulating layer is, for example, an inorganic insulating film such as a silicon nitride layer, a polyimide layer, or an organic insulating layer such as a BCB (Benzocyclobutane) layer. In FIG. 2, the width of the ohmic contact layer 37 and the gate metal layer 39 is larger than the width of the low resistance layer 38, but the width of the ohmic contact layer 37 and the gate metal layer 39 may be the same as the width of the low resistance layer 38. The low resistance layer 38 may not be provided.

### First Comparative Example

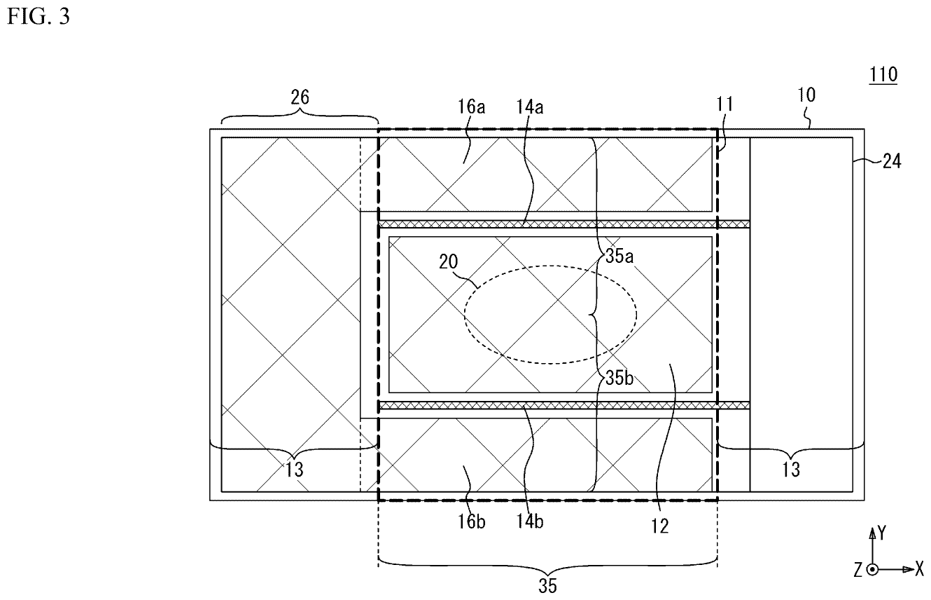

FIG. 3 is a plan view of a semiconductor device according to a first comparative example. As illustrated in FIG. 3, in a semiconductor device 110 according to the first comparative example, the gate electrodes 14c and 14d and the drain electrode 16c are not provided. The gate electrodes 14a and 14b are directly connected to the gate bus bar 24. The drain electrodes 16a and 16b are directly connected to the drain bus bar 26. The drain bus bar 26 is provided on the inactive region 13. In the first comparative example, two unit FETs 35a and 35b are provided for one source electrode 12. The other configuration is the same as that of the first embodiment.

### Second Comparative Example

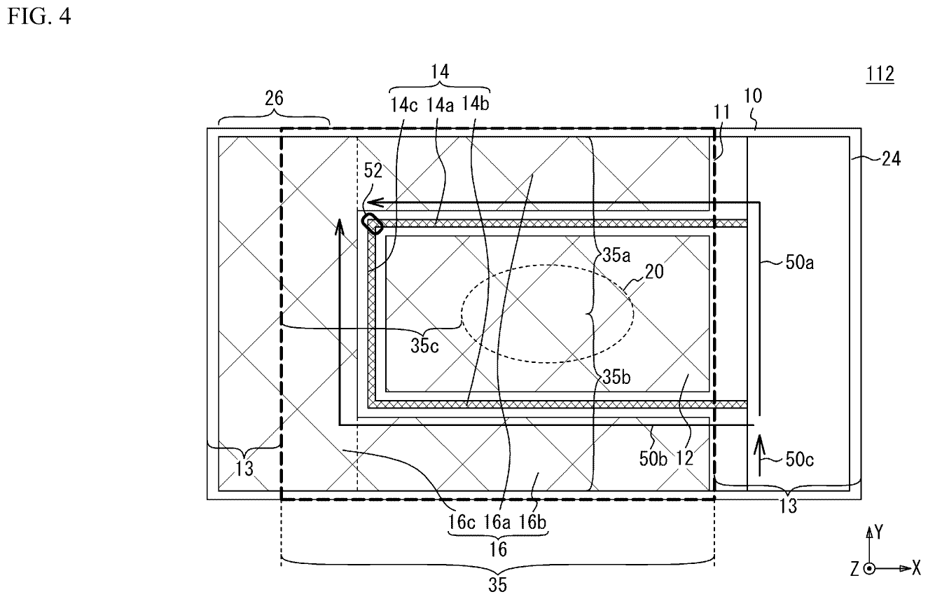

FIG. 4 is a plan view of a semiconductor device according to a second comparative example. As illustrated in FIG. 4, in a semiconductor device 112 according to the second comparative example, the gate electrode 14c is provided to connect the −end of the gate electrode 14a in the X direction and the −end of the gate electrode 14b in the X direction. The drain electrode 16c is provided to connect the −end of the drain electrode 16a in the X direction and the −end of the drain electrode 16b in the X direction. The drain electrode 16c is provided on the active region 11. Thus, three unit FETs 35a to 35c are provided for one source electrode 12. Therefore, the gate width of the unit FET 35 can be made larger than that of the first comparative example. The output of one source electrode 12 can be increased, and a higher output can be achieved. When the same output power is considered, the semiconductor device can be downsized. The other configurations are the same as those of the first embodiment, and the description thereof is omitted.

When a high-frequency signal is supplied from the-end of the gate bus bar 24 in the Y direction as indicated by an arrow 50c, one of the branched signals passes through the gate bus bar 24 and then flows through the gate electrode 14a as indicated by an arrow 50a. The other branched signal flows through the gate electrodes 14b and 14c as indicated by the arrow 50b. The signal flowing through the arrow 50a and the signal flowing through the arrow 50b are merged at a portion 52 where the electric lengths of the arrows 50a and 50b are the same, that is, a point where the gate electrodes 14a and 14c are in contact with each other. Therefore, the unit FET 35 can be effectively regarded as an FET in which two FETs, a first FET having the unit FET 35a and a second FET having the unit FETs 35b and 35c, are connected in parallel. The effective gate widths up to the portion 52 are different between the first FET and the second FET. In this case, when a plurality of unit FETs 35 are arranged to design a high-frequency transistor, it is necessary to consider FETs having different effective gate widths, which makes the design difficult.

### Description of First Embodiment

According to the first embodiment, as illustrated in FIG. 1, the first end of the gate wiring 23 is connected to only one location 51 of the gate electrode 14, and the second end of the gate wiring 23 is connected to the gate bus bar 24. Accordingly, one of the signals branched at the location 51 among the high-frequency signals having passed through the gate wiring 23 passes through a part of the gate electrode 14d and the gate electrode 14a and reaches the portion 52 in the gate electrode 14c as indicated by the arrow 50a. The other branched signal passes through a part of the gate electrode 14d and the gate electrode 14b and reaches the portion 52 in the gate electrode 14c as indicated by an arrow 50b. The portion 52 where the electrical length of the arrow 50a is equal to the electrical length of the arrow 50b is substantially the center of the gate electrode 14c. Thus, the unit FET 35 can be effectively regarded as an FET in which two FETs, i.c., the first FET having the unit FET 35a and a part of the unit FET 35c, and the second FET having the unit FET 35b and a part of the unit FET 35c, are connected in parallel. Compared with the second comparative example, the effective gate widths of the first FET and the second FET can be made closer to each other. Therefore, when a plurality of unit FETs 35 are arranged to design a high-frequency transistor, the design is facilitated. As described above, the semiconductor device 100 of the first embodiment can be downsized because of its easy design.

In the first embodiment, the drain electrode 16 does not surround the gate electrode 14 from the +direction (the direction opposite to the second direction) in the X direction. That is, the drain electrode 16 surrounds the gate electrode 14 only from the +direction in the Y direction, the −direction in the Y direction, and the −direction in the X direction. As described above, the drain electrode 16 may not be provided between the source electrode 12 and the gate bus bar 24. This allows miniaturization.

In FIG. 1, a portion 54 is a portion of the gate electrode 14 not surrounded by the drain electrode 16 in the +direction in the X direction. The width of the portion 54 in the Y direction is W1. The center point of the portion 54 in the Y direction is defined as a center point 53. A range 55 is a range having a width W2 which is ½ of the width W1 of the portion 54 in the Y direction with the center point 53 as the center. In this case, the first end of the gate wiring 23 is connected within the range 55. This makes it possible to make the effective gate widths of the two FETs, which are effectively connected in parallel, of the unit FETs 35 closer to each other. Therefore, when a plurality of unit FETs 35 are arranged to design a high-frequency transistor, the design is easier. The width W2 of the range 55 may be one third or one fourth of the width W1.

The metal layer 28 is provided under the substrate 10 and is electrically connected to the source electrode 12 through a via hole 20 penetrating the substrate 10. This allows the reference potential to be supplied to the source electrode 12. When one via hole 20 is provided in the source electrode 12, the effective gate width of the unit FET 35 per one via hole 20 can be increased. Therefore, the size of the device can be reduced.

The drain electrode 16 has regions surrounding the gate electrode 14 from the +direction and the −direction in the Y direction and from the −direction in the X direction, which are formed on the active region 11. This allows the drain electrode 16c to function as the drain electrode of the unit FET 35c. Therefore, the size of the device can be reduced.

### First Modification of First Embodiment

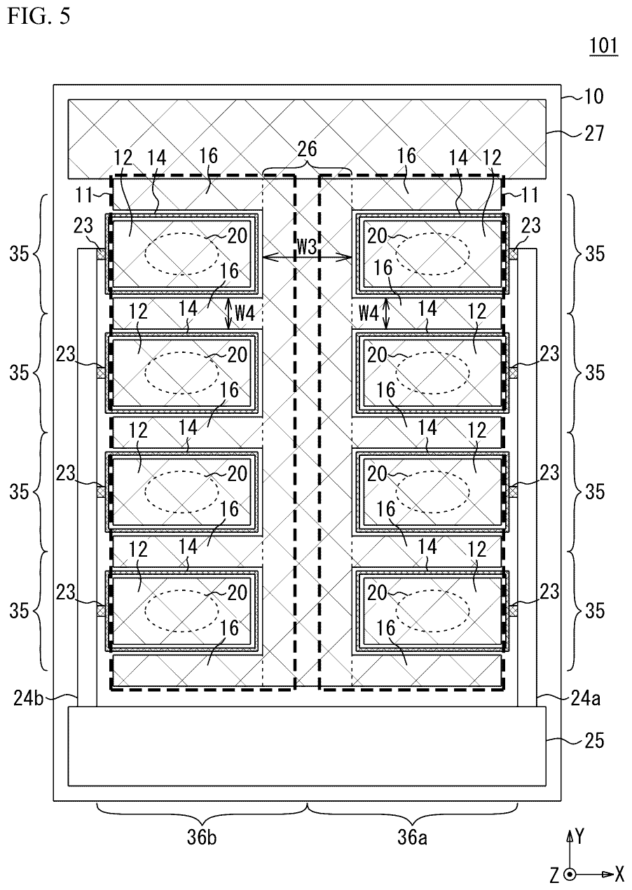

FIG. 5 is a plan view of a semiconductor device according to a first modification of the first embodiment. As illustrated in FIG. 5, in a semiconductor device 101 of the first modification of the first embodiment, FET groups 36a and 36b are arranged in the X direction. The FET groups 36a and 36b include a plurality of unit FETs 35 arranged in the Y direction. The unit FETs 35 adjacent in the Y direction share the drain electrode 16. The FET groups 36a and 36b share the drain bus bar 26 and are provided in mirror symmetry in the X direction with respect to the drain bus bar 26. The gate electrodes 14 of the plurality of unit FETs 35 of the FET group 36a are electrically connected to a gate bus bar 24a and short-circuited. The gate electrodes 14 of the plurality of unit FETs 35 of the FET group 36b are electrically connected to a gate bus bar 24b and short-circuited. The FET group 36a is interposed between the gate bus bar 24a and the drain bus bar 26 in the X direction, and the FET group 36b is interposed between the gate bus bar 24b and the drain bus bar 26 in the X direction.

The gate bus bars 24a and 24b and the drain bus bar 26 extend in the Y direction. A gate pad 25 and a drain pad 27 are provided so that the FET groups 36a and 36b are interposed therebetween in the Y direction. The gate bus bars 24a and 24b are electrically connected to the gate pad 25 at the −end in the Y direction and are short-circuited. The drain bus bar 26 is electrically connected to the drain pad 27 at the +end in the Y direction and is short-circuited. The number of unit FETs 35 each of the FET groups 36a and 36b may be two, three, or five or more. The other configurations are the same as those of the first embodiment, and the description thereof is omitted.

As in the first modification of the first embodiment, the FET group 36a (first FET group) has a plurality of unit FETs 35 arranged in the Y direction, and the drain electrodes 16 of the adjacent unit FETs 35 are shared. The gate electrodes 14 of the plurality of unit FETs 35 of the FET group 36a are electrically connected to the gate bus bar 24a (first gate bus bar). The drain bus bar 26 is connected to the drain electrode 16 of the unit FET 35 of the FET group 36a. The FET group 36a is interposed between the drain bus bar 26 and the gate bus bar 24a. With such a structure, the unit FETs 35 can be arranged in the Y direction, and the gate width of the semiconductor device 101 can be increased. Since the unit FETs 35 having substantially the same characteristics are arranged, the semiconductor device 101 having a large gate width can be easily designed.

The drain bus bar 26 is interposed between the FET groups 36a and 36b (second FET group). The FET group 36b is interposed between the drain bus bar 26 and the gate bus bar 24b (second gate bus bar). This makes it possible to arrange the unit FETs 35 in the Y direction, and to increase the gate width in the semiconductor device 101. Since the unit FETs 35 having substantially the same characteristics are arranged, the semiconductor device 101 having a large gate width can be easily designed.

The gate pad 25 to which the gate bus bars 24a and 24b are connected and the drain pad 27 to which drain bus bar 26 is connected are provided so that the FET groups 36a and 36b are interposed therebetween. This allows the gate potential to be supplied from the gate pad 25 to the gate electrodes 14 of the FET groups 36a and 36b via the gate bus bars 24a and 24b. A drain potential can be supplied from the drain pad 27 to the drain electrodes 16 of the FET groups 36a and 36b via the drain bus bar 26. In this way, the gate pad 25 and the drain pad 27 can be efficiently arranged, and hence the size of the semiconductor device can be reduced.

A current larger than the current of the drain electrode 16 shared by the unit FETs 35 adjacent in the Y direction flows through the drain bus bar 26. By making the current density of the drain bus bar 26 and the current density of the drain electrode 16 shared by the unit FETs 35 adjacent in the Y direction substantially the same, the size can be reduced. Therefore, as illustrated in FIG. 5, the width W3 of the drain bus bar 26 in the X direction is set larger than the width W4 of the drain electrode 16 in the Y direction, which is shared by the unit FETs 35 adjacent to each other in the Y direction. This makes it possible to bring the current density of the drain bus bar 26 close to the current density of the drain electrode 16 shared by the unit FETs 35 adjacent to each other in the Y direction. Therefore, the semiconductor device 101 can be downsized. The width W3 can be 1.5 times or more, or twice or more, the width W4. In order to prevent the current density of the drain bus bar 26 from being too small, the width W3 can be set to be 10 times or less of the width W4.

The width of the source electrode 12 in the X direction is, for example, 0.1 μm or more and 200 μm or less, and is, for example, 50 μm. The width of the source electrode 12 in the Y direction is, for example, 0.1 μm or more and 200 μm or less, and is 50 μm as an example. The gate electrode 14 has a gate length of, for example, 0.05 μm or more and 5 μm or less. The width W3 of the drain bus bar 26 in the X direction is, for example, 10 μm or more and 200 μm or less, and is, for example, 50 μm. The width W4 in the Y direction of the drain electrode 16 shared by the unit FETs 35 adjacent in the Y direction is, for example, 10 μm or more and 100μm or less, and is, for example, 25 μm. The width of the drain electrode 16c in the X direction is 5 μm or more and 50 μm or less, for example, 12 μm. The distance between the gate electrode 14d and the gate bus bars 24a and 24b in the X direction is, for example, 0.1 μm or more and 100 μm or less, and is, for example, 5 μm. The widths of the gate bus bars 24a and 24b in the X direction are, for example, 0.05 μm or more and 500 μm or less, and for example, 30 μm. The width of the gate wiring 23 in the Y direction is, for example, 0.05 μm or more and 500 μm or less, and is 1.0 μm as an example.

### Second Modification of First Embodiment

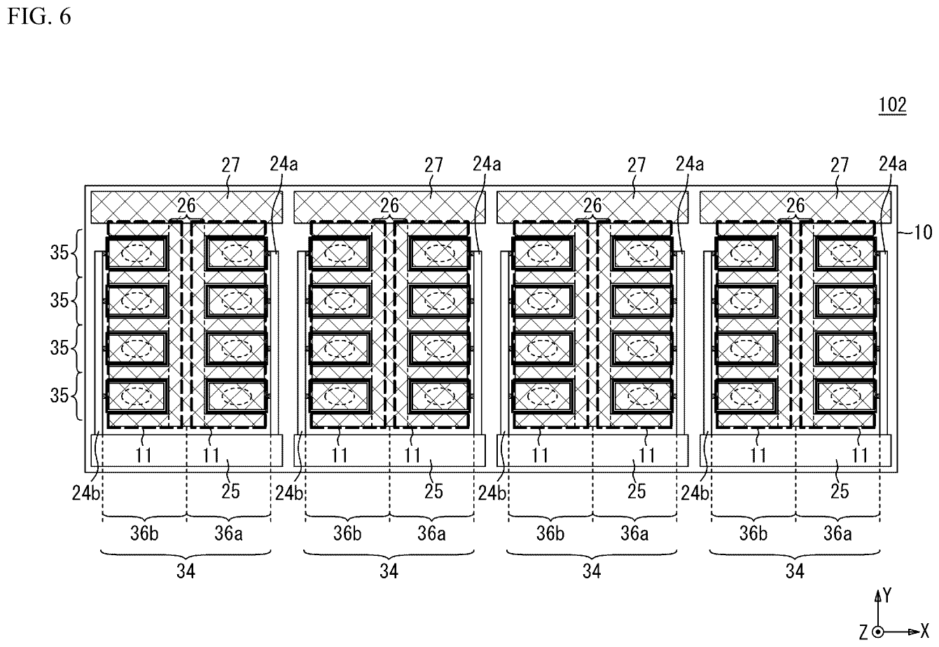

FIG. 6 is a plan view of a semiconductor device according to a second modification of the first embodiment. As illustrated in FIG. 6, in a semiconductor device 102 of the second modification of the first embodiment, a plurality of units 34 each having FET groups 36a and 36b, gate bus bars 24a and 24b, and drain bus bars 26 are arranged in the X direction. The gate pad 25 is provided for each unit 34, and the drain pad 27 is provided for each unit 34. The gate pads 25 of the plurality of units 34 may be provided in a connected manner. The drain pads 27 of the plurality of units 34 may be connected to each other. The number of units 34 may be two, three, or five or more. The other configurations are the same as those of the first modification of the first embodiment, and the description thereof is omitted.

By arranging the units 34 in the X direction as in the second modification of the first embodiment, a plurality of unit FETs 35 can be arranged efficiently. Therefore, the size of the device can be reduced.

### SECOND EMBODIMENT

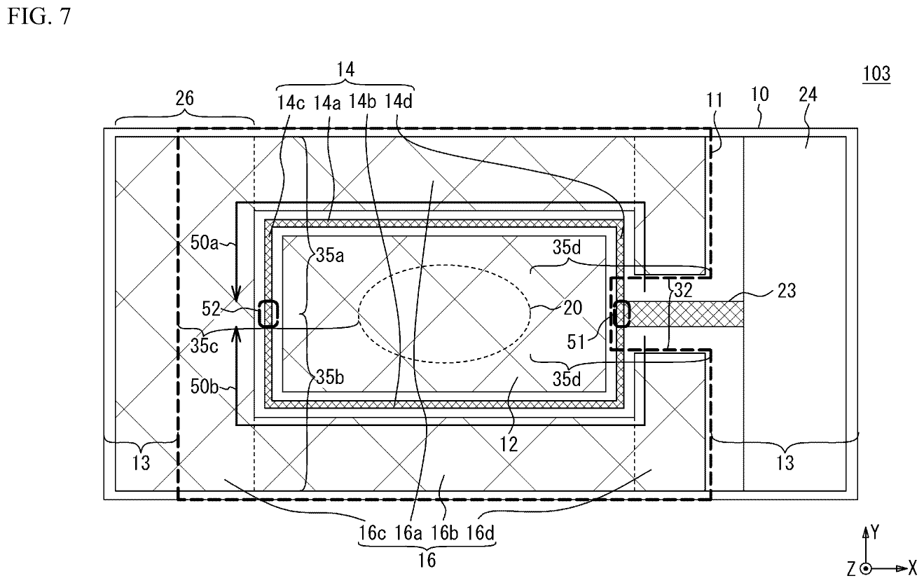

FIG. 7 is a plan view of a semiconductor device according to a second embodiment. As illustrated in FIG. 7, in a semiconductor device 103 of the second embodiment, the drain electrode 16 includes a drain electrode 16d in addition to the drain electrodes 16a to 16c. The drain electrode 16d is provided between the gate electrode 14d and the gate bus bar 24. The drain electrode 16d is provided on the active region 11. A unit FET 35d includes the source electrode 12, the gate electrode 14d, and the drain electrode 16d. The drain electrode 16d is divided into two in the Y direction. A region 32 where the drain electrode 16d is not provided is provided between the divided drain electrodes 16d. The region 32 extends in the X direction. The gate wiring 23 is provided in the region 32 and does not overlap the drain electrode 16d. The gate wiring 23 is provided on the inactive region 13. The other configurations are the same as those of the first embodiment, and the description thereof is omitted.

According to the second embodiment, the drain electrode 16 surrounds the gate electrode 14 from the +direction in the X direction. This makes it possible to increase the effective gate width of the unit FET 35 sharing one source electrode 12, as compared with FIG. 1 of the first embodiment. Therefore, the semiconductor device 103 can be further downsized. For the purpose of miniaturization, the width of the region 32 in the Y direction can be set to be equal to or less than ½ of the width of the gate electrode 14d in the Y direction.

As in the first embodiment, the first end of the gate wiring 23 is connected to only one portion of the gate electrode 14. Thus, the unit FET 35 can be regarded as an FET in which the first FET and the second FET having substantially the same effective gate width are connected in parallel. Therefore, when a plurality of unit FETs 35 are arranged to design a high-frequency transistor, the design is facilitated. In addition, since the effective gate width can be made larger than that of the second comparative example, the size can be reduced.

In the second embodiment, the effective gate width of the FET extending from the portion 51 to the portion 52 through the gate electrode 14a is substantially the same as that of the FET extending from the portion 51 to the portion 52 through the gate electrode 14b, regardless of the position of the portion 51 where the gate wiring 23 is connected to the gate electrode 14. Therefore, the design is easier.

### First Modification of Second Embodiment

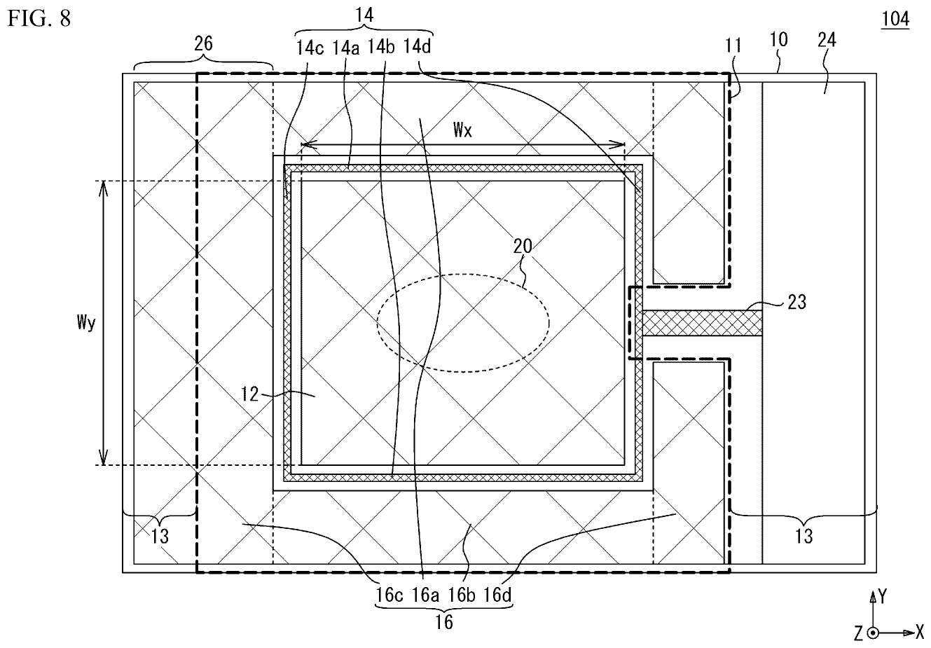

FIG. 8 is a plan view of a semiconductor device according to a first modification of the second embodiment. As illustrated in FIG. 8, in a semiconductor device 104 of the first modification of the second embodiment, the width Wx of the source electrode 12 in the X direction is substantially equal to the width Wy in the Y direction. The source electrode 12 has a substantially square shape in plan view. This makes it possible to maximize the effective gate width of the unit FET 35 when the area of the planar shape of the source electrode 12 is the same. In addition, heat can be isotropically diffused. This improves the heat dissipation. The other configurations are the same as those of the second embodiment, and the description thereof is omitted.

From the viewpoint of increasing the effective gate width and the heat dissipation property, the width Wx can be set to be 3 times or less and 1/3 times or more, 2 times or less and 1/2 times or more, or 1.5 times or less and 1/1.5 times or more the width Wy. In the first embodiment and the modifications thereof, the width Wx can be set to be three times or less and one third or more times the width Wy, can be set to be two times or less and one half or more times the width Wy, or can be set to be 1.5 times or less and one 1.5 times or more times the width Wy.

### Second Modification of Second Embodiment

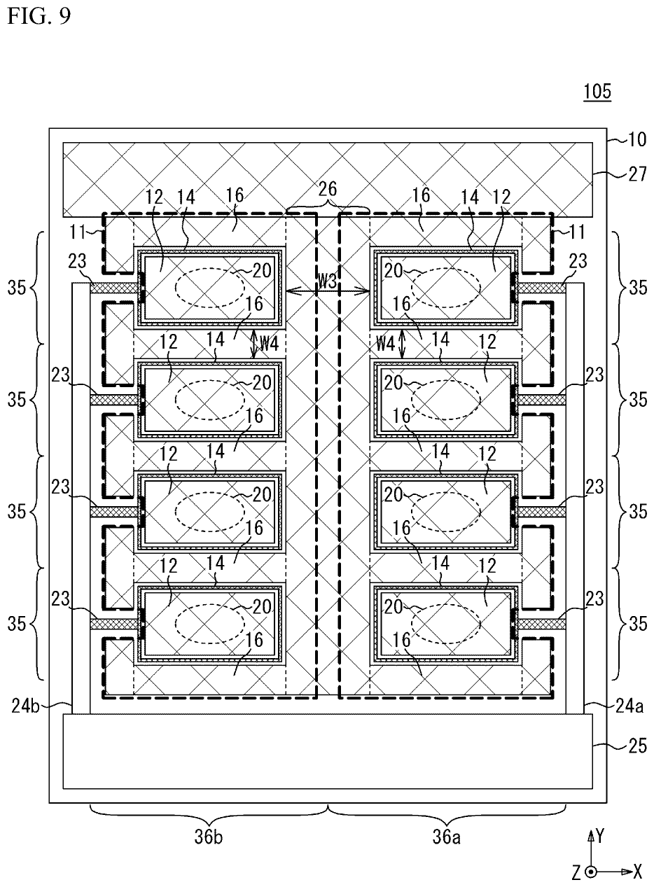

FIG. 9 is a plan view of a semiconductor device according to a second modification of the second embodiment. As illustrated in FIG. 9, in a semiconductor device 105 of the second modification of the second embodiment, the unit FET 35 is the unit FET 35 of the second embodiment. The number of unit FETs 35 each of the FET groups 36a and 36b may be two, three, or five or more. The other configurations are the same as those of the first modification of the first embodiment, and the description thereof will be omitted.

As in the second modification of the second embodiment, the unit FETs 35 having the drain electrodes 16d may be arranged in the Y direction. This makes it possible to increase the gate width in the semiconductor device 105. The width W3 of the drain bus bar 26 in the X direction is larger than the width W4 of the drain electrode 16 shared by the unit FETs 35 adjacent to each other in the Y direction. This allows a current larger than the current flowing through the drain electrode 16 of the unit FET 35 to flow through the drain bus bar 26.

### Third Modification of Second Embodiment

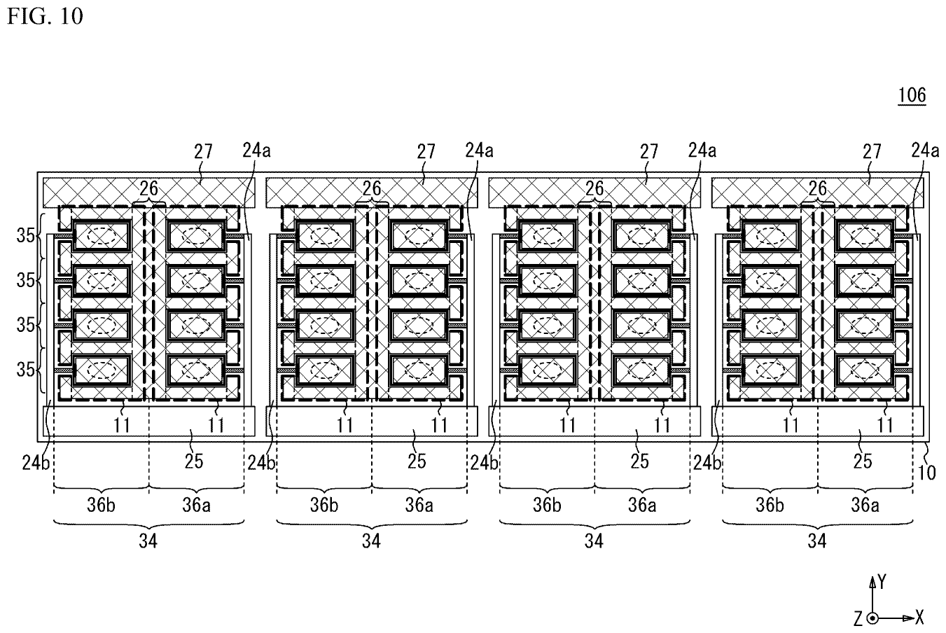

FIG. 10 is a plan view of a semiconductor device according to a third modification of the second embodiment. As illustrated in FIG. 10, in a semiconductor device 106 of the third modification of the second embodiment, the unit FET 35 is the unit FET 35 of the second embodiment. The number of units 34 may be two, three, or five or more. The other configuration is the same as that of the second modification of the first embodiment, and the description thereof is omitted. As in the third modification of the second embodiment, the units 34 may be arranged in the X direction.

### THIRD EMBODIMENT

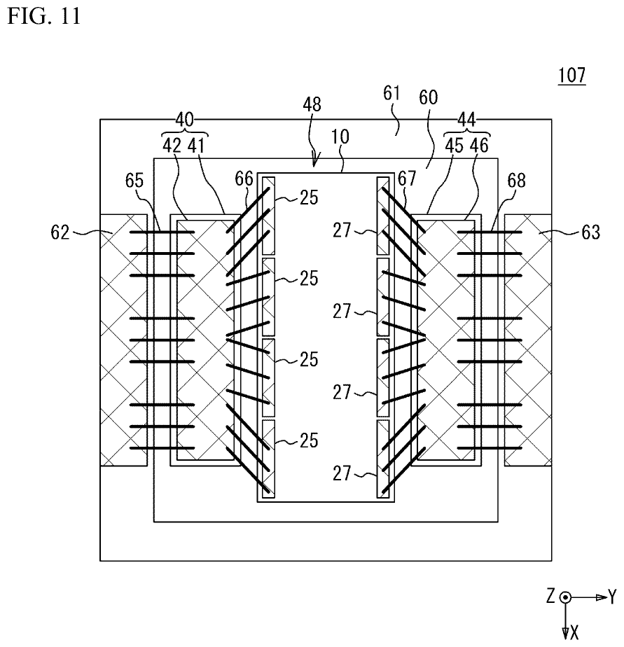

FIG. 11 is a plan view of a semiconductor device according to a third embodiment. As illustrated in FIG. 11, in a semiconductor device 107, an insulating frame 61 made of ceramics or the like is mounted on a base 60 made of metal such as copper. An input terminal 62 and an output terminal 63 are provided on the frame 61. Chips 40 and 44 and a semiconductor chip 48 are mounted on the base 60. The semiconductor chip 48 is, for example, the semiconductor device 102 of FIG. 6 of the second modification of the first embodiment or the semiconductor device 106 of FIG. 10 of the third modification of the second embodiment. The chip 40 includes a dielectric layer 41, a conductor pattern 42 provided on the dielectric layer 41, and a conductor pattern (not illustrated) provided under the dielectric layer 41. The chip 44 includes a dielectric layer 45, a conductor pattern 46 provided on the dielectric layer 45, and a conductor pattern (not illustrated) provided under the dielectric layer 45. The conductor patterns 42 and 46, the input terminal 62, and the output terminal 63 are metal layers such as gold layers. The gate pad 25 and the drain pad 27 are provided on the semiconductor chip 48. In FIG. 11, the unit 34 and the like are not illustrated.

Bonding wires 65 electrically connect the input terminal 62 to the conductor pattern 42. Bonding wires 66 electrically connect the conductor pattern 42 to the gate pad 25. Bonding wire 67 electrically connect the drain pad 27 to the conductor pattern 46. Bonding wires 68 electrically connect the conductor pattern 46 to the output terminal 63.

The conductor pattern 42 sandwiching the dielectric layer 41 and the conductor pattern under the dielectric layer 41 function as a capacitor connected by shunt. The bonding wires 65 and 66 and the chip 40 form an input matching circuit. The conductor pattern 46 sandwiching the dielectric layer 45 and the conductor pattern under the dielectric layer 45 function as a capacitor connected by shunt. The bonding wires 67 and 68 and the chip 44 form an output matching circuit.

The high frequency signal input from the input terminal 62 is input to the semiconductor chip 48 via the chip 40. The high frequency signal amplified in the semiconductor chip 48 is output from the output terminal 63 through the chip 44. As illustrated in FIG. 6 of the second modification of the first embodiment and FIG. 10 of the third modification of the second embodiment, the gate pad 25 and the drain pad 27 are provided on the long side of the substrate 10. Therefore, the bonding wires 66 and 67 can be easily bonded to the gate pad 25 and the drain pad 27. As in the third embodiment, the semiconductor devices of the first and second embodiments and the modifications thereof may have a configuration in which a semiconductor chip is mounted on a package.

The embodiments disclosed herein are to be considered as illustrative in all respects and not restrictive. The scope of the present disclosure is not in the sense set forth above, but is indicated by the claims, and is intended to include all modifications within the meaning and scope of the claims and equivalents.

1. A semiconductor device comprising:
a source electrode provided on a substrate;
a gate electrode provided on the substrate and surrounding a part of the source electrode;
a drain electrode provided on the substrate and surrounding the gate electrode; and
a gate wiring provided on the substrate, wherein a first end of the gate wiring is connected to only one portion of the gate electrode and a second end of the gate wiring is connected to a first gate bus bar.

2. The semiconductor device according to claim 1, wherein
the gate electrode is provided in a loop shape on the substrate.

3. The semiconductor device according to claim 1, wherein
the drain electrode is provided on the substrate and surrounds the gate electrode in a first direction, a direction opposite to the first direction, and a second direction intersecting the first direction.

4. The semiconductor device according to claim 3, wherein the drain electrode surrounds the gate electrode only from the first direction, the direction opposite to the first direction, and the second direction.

5. The semiconductor device according to claim 3, wherein the first end of the gate wiring is connected to a portion of the gate electrode not surrounded by the drain electrode in a direction opposite to the second direction, within a range having a width of ½ of a width of the portion in the first direction with a center point in the first direction.

6. The semiconductor device according to claim 3, wherein the drain electrode surrounds the gate electrode from a direction opposite to the second direction.

7. The semiconductor device according to claim 3, wherein a width of the source electrode in the second direction is not more than three times and not less than one third times the width of the source electrode in the first direction.

8. The semiconductor device according to claim 3, further comprising a metal layer provided under the substrate and electrically connected to the source electrode via a via hole penetrating the substrate.

9. The semiconductor device according to claim 3, wherein the substrate has an active region in which a semiconductor layer in the substrate is activated, and a region of the drain electrode surrounding the gate electrode in the first direction, the direction opposite to the first direction, and the second direction is provided on the active region.

10. The semiconductor device according to claim 3, further comprising:
FET groups each including a plurality of unit FETs arranged in the first direction, each of the unit FETs including the source electrode, the gate electrode, and the drain electrode, and adjacent ones of the unit FETs sharing the drain electrode; and
a drain bus bar to which drain electrodes of a plurality of unit FETs in a first FET group among the FET groups are connected, the first FET group being interposed between the first gate bus bar and the drain bus bar,
the first gate bus bar being connected to gate wirings of the plurality of unit FETs in the first FET group.

11. The semiconductor device according to claim 10, further comprising:
a second FET group included in the FET groups, the drain bus bar being interposed between the first FET group and the second FET group; and
a second gate bus bar connected to a plurality of unit FETs included in the second FET group interposed between the drain bus bar and the second gate bus bar.

12. The semiconductor device according to claim 11, wherein a width of the drain bus bar in the second direction is larger than a width of the drain electrode shared by the unit FETs adjacent to each other in the first direction.

13. The semiconductor device according to claim 11, further comprising:
a gate pad electrically connecting the first gate bus bar and the second gate bus bar; and
a drain pad electrically connected to the drain bus bar, the first FET group and the second FET group being interposed between the drain pad and the gate pad.

14. The semiconductor device according to claim 11, further comprising a plurality of unit arranged in the second direction, each of the plurality of units including the first FET group, the second FET group, the drain bus bar, the first gate bus bar, and the second gate bus bar.
